(19) United States
(12) Patent Application Publication
(10) Pub. No.: US 2023/0378888 A1
(43) Pub. Date: Nov. 23, 2023

(54) ELECTRICAL SYSTEM WITH AN ELECTRICAL POWER MODULE AND A DC LINK CAPACITOR AND METHOD FOR MANUFACTURING SUCH AN ELECTRICAL SYSTEM

(71) Applicant: Valeo eAutomotive Germany GmbH, Erlangen (DE)

(72) Inventor: Tobias KIST, Erlangen (DE)

(73) Assignee: Valeo eAutomotive Germany GmbH, Erlangen (DE)

(21) Appl. No.: 18/247,802

(22) PCT Filed: Sep. 10, 2021
(86) PCT No.: PCT/EP2021/074974

§ 371 Date: Apr. 4, 2023

(30) Foreign Application Priority Data
Oct. 5, 2020 (DE) 10 2020 125 979.4

(51) Int. Cl. H02M 7/537; H01G 4/224; H01L 23/31; H01L 21/56

(52) U.S. Cl. CPC H02M 7/537; H01G 4/224; H01L 23/3121; H01L 21/56; H01G 4/32

(57) ABSTRACT

An electrical system includes a power module and a DC link capacitor. The power module includes first and second facing substrates that define between them an inner space of the power module. The power module comprises switches supported by the first or second substrate and extending in the inner space of the power module, and inner electrical conductors extending in the inner space of the power module and connecting the switches. The inner electrical conductors include two inner DC electrical conductors for receiving a DC voltage (E). The DC link capacitor comprises two capacitor electrical conductors facing each other and extending at least partially outside the inner space of the power module and respectively connected to the inner DC electrical conductors for stabilizing the DC voltage (E). The electrical system comprises an overmolding encapsulating at least partially the substrates, the switches, the inner electrical conductors and the capacitor electrical conductors.

The present invention relates to an electrical system with an electrical power module and a DC link capacitor. The invention also relates to a method for manufacturing such an electrical system. This invention can be applied in particular in the automotive industry.

A power module may comprise two substrates facing each other and defining between them an inner space of the power module. At least one of the substrates supports electrical components (for example switching electrical components), as well as electrical conductors for connecting the electrical components, all extending in the inner space.

In particular, such electrical power module may be connected to a DC voltage source via two lead frame terminals.

In order to stabilize the DC voltage provided by the DC voltage source, a DC link capacitor may be used. A DC link capacitor generally comprises two capacitor electrical conductors (often in the form of facing metallic plates or surfaces) separated by a dielectric medium.

There may be parasitic inductance between the electrical power module and the DC link capacitor, resulting from the distance between the electrical power module and the DC link capacitor. This parasitic inductance leads to voltage overshoots during switching events. Such a voltage overshoot limits the switching speed as well as it increases the switching losses. When the electrical power module is used in a traction inverter, this results in a limiting factor of the efficiency of the traction inverter and of the possibility to fully use the performance of SiC based power semiconductors for example.

Published European application for patent No. 2 717 460 A1 discloses an inverter comprising a control device, three single phase power modules and a DC link capacitor. The inverter comprises DC terminals to be connected to a DC voltage source. The DC link capacitor is connected to the DC terminals to smooth the DC voltage provided by the DC voltage source. Each power module comprises two semiconductor switches connected in series and controlled by the control device such that the power modules convert the DC voltage into a three-phase AC voltage for driving an electric motor.

Published US-American application for patent No. 2008/0192437 A1 discloses a module comprising a power semiconductor element and a capacitor having their electrodes joined to each other. The power semiconductor element is formed on a semiconductor substrate having first and second main surfaces. The power semiconductor module includes an electrode through which a main current flows, joined to the first main surface, an electrode through which the main current flows, joined to the second main surface, and a resin portion sealing the semiconductor substrate, the capacitor and the electrodes. The electrode of the capacitor and the electrode of the semiconductor element are joined to each other by solder such that surfaces exposed through the resin portion are arranged on one continuous surface on which a cooler can be attached.

An object of the invention is to provide an improved electrical system with an electrical power module and a DC link capacitor, in particular one which has reduced parasitic inductances.

The object of the invention is solved by means of an electrical system comprising:

Electrical system comprising:
a power module comprising:
   a first substrate,
   a second substrate facing said first substrate, the first and second substrates defining between them an inner space of the power module,
   two switches connected in series, forming a switching leg, and supported by the first or second substrate and extending in the inner space of the power module, and
   inner electrical conductors extending in the inner space of the power module and connecting the switching leg, the inner electrical conductors including two inner DC electrical conductors for receiving a DC voltage;
a DC link capacitor connected in parallel to the switching leg and comprising two capacitor electrical conductors facing each other and extending at least partially outside the inner space of the power module and respectively connected to the inner DC electrical conductors for stabilizing the DC voltage; and
an overmolding encapsulating at least partially, preferably completely, the substrates, the switches, the inner electrical conductors, the DC link capacitor with its capacitor electrical conductors.

The inventive electrical system, thus, comprises the two switches which may be semiconductor switches, and the DC link capacitor encapsulated by means of the overmolding. Thus, the inventive electrical system basically is a power module which integrates the DC link capacitor.

The switches are connected in series and form a switching leg. Switching legs are configured to convert a DC voltage into an AC voltage, as it is known for conventional power modules as it is, for instance, known from published European application for patent No. 2 717 460 A1 mentioned in the introduction.

Thanks to the invention, the DC link capacitor is integrated with the electrical power module. This direct integration makes possible to have a relatively short distance between the electrical power module and the DC link capacitor, which makes possible to increase the efficiency and power of the module. In particular, the invention makes possible to keep a relative high capacitance while obtaining a significant reduction of the voltage overshoot as well as a reduction in switching losses.

This direct integration can also reduce the manufacturing costs of the traction inverter as well as reducing the developing costs of the whole system on hardware level. The fact that resulting device forms one single unit is also advantageous for manipulation.

Optionally, two respective portions of the capacitor electrical conductors extend in the inner space of the power module and are respectively bonded to the inner DC electrical conductors, for example by soldering.

Also optionally, each substrate comprises a non-conductive core layer with an inner surface oriented towards the other substrate, an inner conductive layer being applied on this inner surface of the core layer, and the inner conductive layer of at least one of the substrates forms at least one of the inner DC electrical conductors.

Also optionally, the inner conductive layer of one of the substrates forms both inner DC electrical conductors.

Also optionally, the inner conductive layer of one of the substrates forms one of the inner DC electrical conductors and the inner conductive layer of the other of the substrates forms the other of the inner DC electrical conductors.

Also optionally, for each substrate, an outer conductive layer is being applied on an outer surface of the core layer, opposite the inner surface of the core layer, and the electrical system further comprises a cooling system for cooling each outer conductive layer.

Also optionally, the capacitor electrical conductors are two electrically conducting films.

Also optionally, the films are rolled up together.

The object is also solved by means of a method for manufacturing an electrical system according to any one of the preceding claims, comprising the following steps:
connecting the two capacitor electrical conductors of the DC link capacitor to the inner DC electrical conductors of the power module; then
overmolding at least partially the substrates, the switches, the inner electrical conductors and the DC link capacitor with its capacitor electrical conductors.

Optionally, the method further comprises: obtaining the DC link capacitor;

separating two respective portions of the capacitor electrical conductors; and connecting the capacitor electrical conductors to the inner DC electrical conductors comprises inserting the separated portions into the inner space of the power module and connecting the separated portions to the DC electrical conductors

The invention will be better understood with the aid of the description which follows, given only by way of example and made with reference to the accompanying drawings in which:

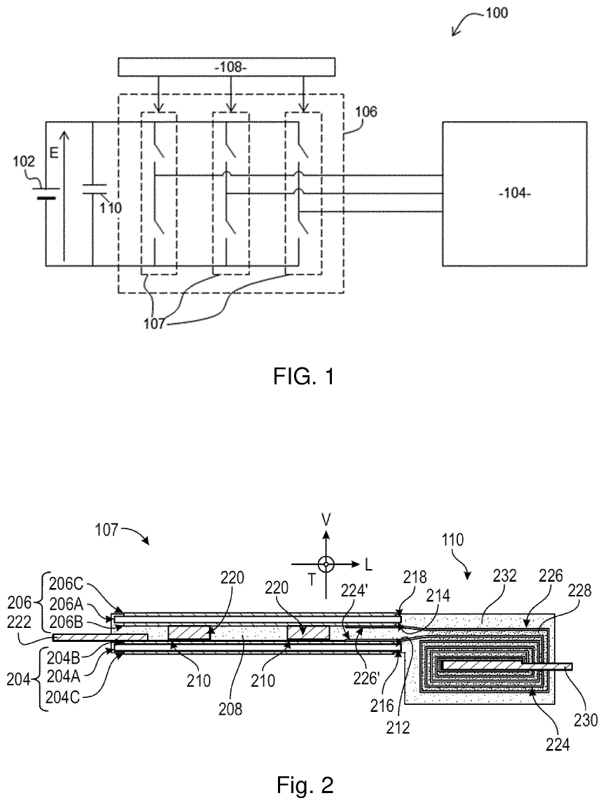

FIG. 1 is a diagram illustrating elements of an electrical system according to the invention,

FIG. 2 is a cross-section view of a combined electrical power module and DC link capacitor of the electrical system of FIG. 1 according to the invention, and

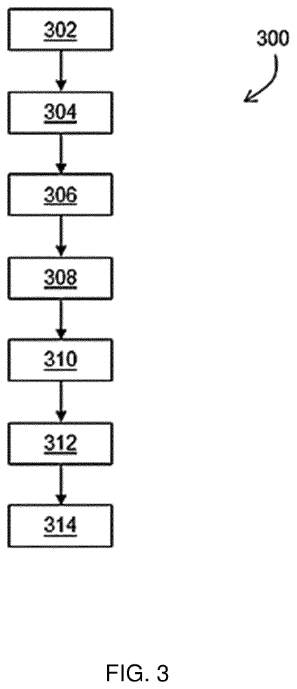

FIG. 3 is a block diagram illustrating steps of an example of a method for manufacturing the combined electrical power module and DC link capacitor of FIG. 2.

Referring to FIG. 1, an electrical system 100 according to the invention will now be described. This electrical system 100 is for example intended to be integrated into an automotive car (not illustrated).

The electrical system 100 comprises a DC voltage source 102, such as a battery, configured to provide a DC voltage E. The DC voltage source 102 comprises a positive terminal and a negative terminal between which the DC voltage E is provided.

The electrical system 100 further comprises a rotary electric machine 104 comprising stator phases. In the described example, the rotary electric machine 104 is of the alternator-starter type, connected to a heat engine of the automotive car. The rotary electric machine 104 can be operated in an engine mode where it helps the heat engine and in an alternating mode where it transforms a part of the mechanical energy produced by the heat engine into electrical energy for reloading the DC voltage source 102.

The electrical system 100 further comprises a voltage converter 106 connected, on the one hand, to the DC voltage source terminals and, on the other hand, to the rotary electric machine 104.

The voltage converter 106 comprises switch legs respectively associated to the stator phases. Each switch leg comprises an upper switch connected to the positive terminal of the DC voltage source 102 and a lower switch connected to the negative terminal of the DC voltage source 102. The upper switch and the lower switch are connected to each other at a middle point connected to the associated stator phase.

Each switch leg is intended to be controlled to switch between two configurations. In the first one, called upper configuration, the upper switch is closed and the lower switch is open so that the DC voltage E is applied to the associated stator phase. In the second one, called lower configuration, the upper switch is open and the lower switch is closed so that a zero voltage is applied to the associated stator phase.

The voltage converter 106 comprises electrical power modules 107 respectively implementing the switch legs.

The electrical system 100 further comprises a module control device 108, so as to commute each arm between these two configurations. In the described example, the voltage converter 106 is controlled as an inverter so as to provide electric energy to the rotary electric machine 104 when the latter must operate in an engine mode. However, the voltage converter 106 is controlled as a rectifier so as to provide electric energy to the DC voltage source 102 (for instance to charge it) when the rotary electric machine 104 must operate in an alternator mode.

The switches are semi-conductor switches comprising transistors for instance. The switches are for example Metal Oxide Semiconductor Field Effect Transistor (MOSFET) or Insulated Gate Bipolar Transistor (IGBT).

The electrical system 100 further comprises a DC link capacitor 110 connected between the two terminals of the DC voltage source 102 for stabilizing the DC voltage E.

In the following description, the different elements are spatially identified in an arbitrary orthogonal mark comprising a vertical direction V, a longitudinal direction L, and a transverse direction T.

Referring to FIG. 2, an example of an electrical device combining one of the power module 107 and the DC link capacitor 110 of FIG. 1, is going to be described in a more detailed manner.

The electrical power module 107 comprises two substrates 204, 206 facing each other. These substrates 204, 206 extend according to a plane defined by L and T directions. The lower substrate 204 along the V direction is called “first substrate”, and the upper substrate 206 along the V direction is called “second substrate”.

The substrates 204, 206 define between them an inner space 208 of the power module 107.

The electrical power module 107′ further comprises two switches 210 supported by at least one of the substrates 204, 206 and extending in the inner space 208. In the described example, each switch 210 is a chip encapsulating one of the semi-conductor switches of the switch leg. Furthermore, in this example, the inner switches 210 are supported by the first substrate 204 or by the second substrate 206.

Each substrate 204, 206 is advantageously an electrical substrate, i.e. configured to provide electrical connectors for connecting the switches 210, in addition to the mechanical support. Generally, an electrical substrate comprises for example a plate or a metallic blade or a printed circuit board comprising electronic tracks for electrically connecting the switches 210 between them and/or with an external electrical circuit.

In the described example, each substrate 204, 206 comprises a non-conductive core layer 204A, 206A with an inner surface 212, 214 oriented towards the other substrate 204, 206.

In this example, according to the V direction, each core layer 204A, 206A has an upper side and a lower side. The upper side of the core layer 204A of the first substrate 204 corresponds to its inner surface 212, while the lower side of the core layer 206A of the second substrate 206 corresponds to its inner surface 214.

An inner conductive layer 204B is applied on the inner surface 212 of the core layer 204A of the first substrate 204. Similarly, an inner conductive layer 206B is also applied on the inner surface 214 of the core layer 206A of the second substrate 206.

These inner conductive layers 204B, 206B are configured to form electrical conductors extending in the inner space 208 connecting the switches 210 according to the desired circuit, for implementing a switch leg in the described example. In particular, these electrical conductors include two DC electrical conductors for receiving a DC voltage, the DC voltage E in the described example.

In particular, a lower face of each inner electrical component 210 may be electrically and/or mechanically bonded to one of the substrates 204, 206. In the described example, this lower face is bonded, for example by soldering, to at least one electrical conductor formed in the inner conductive layer 204.

Optionally, outer surfaces 216, 218 of the core layers 204A, 206A (i.e. respectively the lower side of the core layer 204A and the upper side of the core layer 206A) can be coated with an outer conductive layer 204C, 206C. These outer conductive layers 204C, 206C are thermally conductive, so as to dissipate heat out of the electrical power module 107. The electrical power module 107 may further comprise a cooling system (not depicted) for cooling each outer conductive layers 204C, 206C, so as to form a double sided cooled module.

For example, each substrate 204, 206 may be a Direct Bonded Copper substrate (DCB substrate) comprising a ceramic core 204A, 206A coated on one or two faces with copper. Alternatively, the substrates 204, 206 can be composed of a metallic plate (i.e. aluminum plate), covered with a dielectric layer that is covered with a copper layer. In this case, the metallic plate corresponds to the outer conductive layer, the dielectric layer corresponds to the core layer, and the copper layer corresponds to the inner conductive layer.

Spacers 220 may be arranged in the inner space 208 between both substrates 204, 206, so as to keep a predetermined distance between them. For example, each spacer 220 extends from an electrical components supported by one of the substrates to the other substrate. In the described example, each spacer 220 extends from one to the switches 210 to the second substrate 206. In this manner, each spacer 220 may be used to transfer heat to the second substrate 206 to improve heat dissipation and may be used to electrically connect an upper surface of the inner electrical component 210 to electrical conductors formed in the inner conductive layer 206B of the second substrate 206.

The electrical power module 107 further comprises at least one external electrical conductor 222 extending from the inner space 208 of the power module 107 to outside of the inner space 208, for connecting the inner electrical conductors and/or directly the switches 210 to external electrical components, such as other electrical components of the voltage converter 106 as illustrated on FIG. 1.

Each external electrical conductor 222 advantageously comprises a rigid lead frame, for example substantially planar. These lead frames are, for example, metallic. They extend in a rectilinear manner and/or are shaped with bend and/or plane variation if needed.

In the described example, the external electrical conductor 222 has a first end (on the left) intended to be connected to a phase of the rotary electric engine 104, and a second end (on the right) connected to an inner electrical conductor of the first substrate 204.

The DC link capacitor 110 comprises at least two capacitor electrical conductors 224, 226 facing each other and separated by a dielectric medium 228. In the described example, the capacitor electrical conductors 224, 226 respectively comprise two superimposed metallized films rolled up together.

A small portion 224′, 226′ (e.g. less than 10%) of each film 224, 226 extends in the inner space 208 of the electrical power module 107, while the remainder extends outside the inner space 208. These portions 224′, 226′ are separated from each other (the dielectric medium 228 may be removed between these portions 224′, 226′) and respectively bonded to the inner DC electrical conductors, for example directly such as by soldering. Because most of the capacitor electrical conductors extends outside of the inner space 208, they can be large so that the DC link capacitor can achieve a high capacitance, for example greater than 50 μF, for example between 50 μF and 100% F.

Except on these small portions 224′, 226′, the two capacitor electrical conductors 224, 226 preferably always keep a short and substantially constant distance between them, for example thanks to the dielectric medium 228 extending therebetween.

In the described example, one inner DC electrical conductor is on the first substrate 204, while the other inner DC electrical conductor is on the second substrate 206. In this case, the two portions 224′, 226′ are separated in the V direction to be respectively bonded to the two substrates 204, 206.

In another possible embodiment, not depicted, the portions 224′, 226′ of the films 224, 226 may be splitted in the T direction, and bonded to the same substrate (first or second), while being spaced from each other, so as to avoid entering into contact.

The DC link capacitor 110 may further comprise two external DC electrical conductors 230 for connecting the DC link capacitor 110 to external components (different from the electrical power module 107). The external DC electrical conductors have one end respectively connected (i.e. bonded) to the films 224, 226 and another end intended to receive for example a DC voltage, such as the DC voltage E in the described example. Preferably, each external DC electrical conductor 230 comprises a rigid lead frame, for example substantially planar. These lead frames are, for example, metallic. They extend in a rectilinear manner and/or are shaped with bend and/or plane variation if needed.

The combined electrical power module and DC link capacitor further comprises an overmolding 232, that is electrically insulating, rigid, and that encapsulates at least partially the substrates 204, 206, the switches 210, the inner electrical conductors and the capacitor electrical conductors. Preferably, the overmolding 232 coats entirely the switches 210. The overmolding 232 comprises for example an epoxy resin. The overmolding 232 is for example made by transfer molding, or by compression molding. For example, the switches 210 are drowned in the overmolding 232 so as to accomplish an encapsulation, i.e. the coating/over-molding. Preferably, at least a portion (e.g. the portion extending in the inner space 208) of the external electrical conductor 222 is also encapsulated. Preferably, the outer conductive layers 204C, 206C are not encapsulated in order to be cooled, at least their outer surfaces. Preferably, the overmolding 232 fills entirely the inner space 208. The overmolding 232 is illustrated by the area with points on the figures.

As it is clear from the previous description, the DC link capacitor 110 is integrated with the module 107 and not an annex component as in the prior art. The module 107 with its integrated DC link capacitor 110 therefore forms a single unit. Preferably, the encapsulation is such that there is no possible disassembly, without deteriorating the encapsulated elements. This direct integration of the DC link capacitor 110 into the electrical power module 107 leads to a reduced distance between the DC link capacitor and the electrical power module 107, such that a very low parasitic inductance is obtained, while keeping the possibility of a very large capacitance, which leads to a significant reduction of the voltage overshoot as well as a reduction in switching losses.

Referring to FIG. 3, an example of method 300 for manufacturing the combined electrical power module and DC link capacitor will now be described.

At a step 302, the electrical power module 107 and the DC link capacitor 110 are obtained, without the overmolding 232.

At a step 304, the portions of the capacitor electrical conductors are separated one from another.

At a step 306, the separated portions are inserted into the inner space 208 of the electrical power module 107.

At a step 308, the separated portions are inserted into the inner space 208 of the electrical power module 107.

At a step 310, the inserted portions are respectively bonded to the inner DC electrical conductors, for example directly, for example par soldering. As a result, the two capacitor electrical conductors are connected to the inner DC electrical conductors and extend very closely to the inner DC electrical conductors, so that the parasitic inductance is low.

At a step 312, the substrates 204, 206, the switches 210, the inner electrical conductors and the capacitor electrical conductors 224, 226 are encapsulated by being at least partially overmolded to form the overmolding 232.

The encapsulation can be made in a single step to form a single overmolding: the substrates 204, 206 (preferably except the outer conductive layers), the switches 210, the inner electrical conductors, the capacitor electrical conductors 224, 226 and part of the external electrical conductors 222, 230 are encapsulated at the same time.

Alternatively, the encapsulation can be made in two steps: the substrates 204, 206 (preferably, except the outer conductive layers), the switches 210, the inner electrical conductors and part of the external electrical conductors 222 of the electrical power module 107 encapsulated in a first step, and then the capacitor electrical conductors 224, 226 and part of the external electrical conductors 230 of the DC link capacitor 110 encapsulated in a second step.

It will be noted that the invention is not limited to the embodiments described above. It will indeed appear to those skilled in the art that various modifications can be made to the embodiments described above, in the light of the teaching which has just been disclosed.

In the previous detailed description of the invention, the terms used should not be interpreted as limiting the invention to the embodiments presented in the present description, but should be interpreted to include all the equivalents within the reach of those skilled in the art by applying their general knowledge to the implementation of the teaching which has just been disclosed.

1. Electrical system comprising:
a power module comprising:
a first substrate,
a second substrate facing said first substrate, the first and second substrates defining between them an inner space of the power module,
two switches connected in series, forming a switching leg and supported by the first or second substrate and extending in the inner space of the power module, and
inner electrical conductors extending in the inner space of the power module and connecting the switching leg, the inner electrical conductors including two inner DC electrical conductors for receiving a DC voltage;
a DC link capacitor connected in parallel to the switching leg and comprising two capacitor electrical conductors facing each other and extending at least partially outside the inner space of the power module and respectively connected to the inner DC electrical conductors for stabilizing the DC voltage; and
an overmolding encapsulating at least partially the substrates, the switches, the inner electrical conductors, the DC link capacitor with its capacitor electrical conductors.

2. Electrical system according to claim 1, wherein two respective portions of the capacitor electrical conductors extend in the inner space of the power module and are respectively bonded to the inner DC electrical conductors, for example by soldering.

3. Electrical system according to claim 1, wherein each substrate comprises a non-conductive core layer with an inner surface oriented towards the other substrate, an inner conductive layer being applied on this inner surface of the core layer, and wherein the inner conductive layer of at least one of the substrates forms at least one of the inner DC electrical conductors.

4. Electrical system according to claim 3, wherein the inner conductive layer of one of the substrates forms both inner DC electrical conductors.

5. Electrical system according to claim 3, wherein the inner conductive layer of one of the substrates forms one of the inner DC electrical conductors and the inner conductive layer of the other of the substrates forms the other of the inner DC electrical conductors.

6. Electrical system according to claim 3, wherein, for each substrate, an outer conductive layer is being applied on an outer surface of the core layer, opposite the inner surface of the core layer, and further comprising a cooling system for cooling each outer conductive layer.

7. Electrical system according to claim 1, wherein the capacitor electrical conductors are two electrically conducting films.

8. Electrical system according to claim 7, wherein the films are rolled up together.

9. Method for manufacturing an electrical system according to claim 1, comprising the following steps:
connecting the two capacitor electrical conductors of the DC link capacitor to the inner DC electrical conductors of the power module; then
overmolding at least partially the substrates, the switches, the inner electrical conductors and the DC link capacitor with its capacitor electrical conductors.

10. Method according to claim 9, further comprising:
obtaining the DC link capacitor;
separating two respective portions of the capacitor electrical conductors;
and wherein connecting the capacitor electrical conductors to the inner DC electrical conductors comprises inserting the separated portions into the inner space of the power module and connecting the separated portions to the DC electrical conductors.

11. Electrical system according to claim 2, wherein each substrate comprises a non-conductive core layer with an inner surface oriented towards the other substrate, an inner conductive layer being applied on this inner surface of the core layer, and wherein the inner conductive layer of at least one of the substrates forms at least one of the inner DC electrical conductors.

12. Electrical system according to claim 4, wherein, for each substrate, an outer conductive layer is being applied on an outer surface of the core layer, opposite the inner surface of the core layer, and further comprising a cooling system for cooling each outer conductive layer.

13. Electrical system according to claim 2, wherein the capacitor electrical conductors are two electrically conducting films.

14. Method for manufacturing an electrical system according to claim 2, comprising the following steps:
connecting the two capacitor electrical conductors of the DC link capacitor to the inner DC electrical conductors of the power module; then
overmolding at least partially the substrates, the switches, the inner electrical conductors and the DC link capacitor with its capacitor electrical conductors.

15. Electrical system according to claim 5, wherein, for each substrate, an outer conductive layer is being applied on an outer surface of the core layer, opposite the inner surface of the core layer, and further comprising a cooling system for cooling each outer conductive layer.

16. Electrical system according to claim 3, wherein the capacitor electrical conductors are two electrically conducting films.

17. Method for manufacturing an electrical system according to claim 3, comprising the following steps:
connecting the two capacitor electrical conductors of the DC link capacitor to the inner DC electrical conductors of the power module; then
overmolding at least partially the substrates, the switches, the inner electrical conductors and the DC link capacitor with its capacitor electrical conductors.

18. Electrical system according to claim 4, wherein the capacitor electrical conductors are two electrically conducting films.

19. Method for manufacturing an electrical system according to claim 4, comprising the following steps:
connecting the two capacitor electrical conductors of the DC link capacitor to the inner DC electrical conductors of the power module; then
overmolding at least partially the substrates, the switches, the inner electrical conductors and the DC link capacitor with its capacitor electrical conductors.

20. Electrical system according to claim 5, wherein the capacitor electrical conductors are two electrically conducting films.
